(19) United States
(12) Patent Application Publication
(10) Pub. No.: US 2025/0056985 A1
(43) Pub. Date: Feb. 13, 2025

(54) DISPLAY PANELS AND DISPLAY APPARATUSES

(71) Applicant: BOE Technology Group Co., Ltd., Beijing (CN)

(72) Inventors: Ming YANG, Beijing (CN); Xuan FENG, Beijing (CN); Zhenyu ZHANG, Beijing (CN); Minghua XUAN, Beijing (CN)

(21) Appl. No.: 18/697,442

(22) PCT Filed: Jan. 6, 2023
(86) PCT No.: PCT/CN2023/071008

§ 371 Date: Mar. 29, 2024

(51) Int. Cl. H10K 59/131; H10K 59/35

(52) U.S. Cl. CPC H10K 59/131; H10K 59/35

(57) ABSTRACT

A display panel and a display apparatus are provided. A display region of the display panel includes a first display region and a transition display region, and a transmittance of the first display region is greater than that of the transition display region. The display panel includes: light-emitting unit groups, first drive circuits, first signal lines and second signal lines. The light-emitting unit groups are in the first display region, and at least one light-emitting unit group includes light-emitting units; the first drive circuits are in the transition display region and electrically connected with the light-emitting unit groups; the first signal lines are between the first drive circuits and the light-emitting unit groups to electrically connect the first drive circuits with the light-emitting unit groups; the second signal lines are electrically connected with the first signal lines and between the light-emitting units to electrically connect the light-emitting units in the at least one light-emitting unit group.

### TECHNICAL FIELD

The present disclosure relates the field of display technologies and in particular to a display panel and a display apparatus.

### BACKGROUND

In the field of display technologies, full screen design is a mainstream trend for display screen development. At present, one of research hotpots is that transparent display design is employed for an under-display camera region in the Active Matrix Organic Light Emitting Diode (AMOLED) display panels to achieve full screen design.

Furthermore, the full screen design also faces many difficulties in designing and manufacturing process, for example, the position of the receiver and the front camera, the problem of how to solve front fingerprint recognition or the like. The design of the front camera has been updated and iterated many times from the flexible screen of the first-generation full screen to the Notch screen (specially-shaped screen), water drop screen, mechanical full screen (pop-up camera), or AA-hole full screen or the like of the second-generation full screen. In recent years, the third-generation full screen emerges, that is, the era of under-display camera comes up. But, the under-display camera still has technical difficulties in truly achieving full screen display. Along with the development of sciences and technologies, display technologies have drawn more and more attention of people. The existing display apparatuses have the problem of low display resolution.

### SUMMARY

For the defects in the prior arts, the present disclosure provides a display panel and a display apparatus so as to solve the technical problems of complex wiring, high material costs or low transmittance of a display region with a photosensitive element in the display panel in the prior arts.

An embodiment of the present disclosure provides a display panel. A display region of the display panel includes a first display region and a transition display region adjacent to each other, and a transmittance of the first display region is greater than a transmittance of the transition display region. The display panel includes: light-emitting unit groups, first drive circuits, first signal lines and second signal lines. The first light-emitting unit groups are in the first display region, and at least one light-emitting unit group of the light-emitting unit groups includes light-emitting units; the first drive circuits are in the transition display region, and the first drive circuits are electrically connected with the light-emitting unit groups; the first signal lines are between the first drive circuits and the first light-emitting unit groups to electrically connect the first drive circuits with the first light-emitting unit groups; and the second signal lines are electrically connected with the first signal lines and disposed between the light-emitting units to electrically connect the light-emitting units in the at least one light-emitting unit group.

In some embodiments, at least one light-emitting unit of the light-emitting units includes sub-light-emitting units, at least two sub-light-emitting units of the sub-light-emitting units have different luminous colors, and the second signal lines electrically connect the at least two sub-light-emitting units having different luminous colors in the light-emitting unit group respectively.

In some embodiments, the first signal lines are sequentially distributed on a plane of the display region, and orthographic projections of the first signal lines electrically connected with a same light-emitting unit group onto the plane of the display region do not overlap.

In some embodiments, there is an overlapping region between orthographic projections of the first signal lines onto a plane of the display region and orthographic projections of the second signal lines onto the plane of the display region.

In some embodiments, the sub-light-emitting units having a same luminous color in a same light-emitting unit group are electrically connected with each other via one of the second signal lines.

In some embodiments, orthographic projections of the second signal lines onto a plane of the display region do not overlap.

In some embodiments, the first drive circuits are sequentially arranged as a first, second, third . . . and m^{th} drive circuits along a direction away from the first display region, the light-emitting unit groups are sequentially arranged as a first, second, third . . . and n^{th} light-emitting unit groups along a direction away from the transition display region, and the drive circuit and the light-emitting unit group having a same sequence number are electrically connected with each other, wherein m and n are positive integers greater than or equal to 1.

In some embodiments, light-emitting units in the n^{th} light-emitting unit group electrically connected with the m^{th} drive circuit are alternately distributed in rows, and the m^{th} drive circuit is in a same row as at least one of the light-emitting units in the n^{th} light-emitting unit group.

In some embodiments, at least one first drive circuit of the first drive circuits includes sub-drive circuits, and the sub-drive circuits are sequentially arranged as a first, second, third . . . and i^{th} sub-drive circuits along the direction away from the first display region; where the sub-light-emitting units in a light-emitting unit in a same row as the sub-drive circuits are sequentially arranged as a first, second, third . . . and j^{th} sub-light-emitting units along the direction away from the transition display region; and where the sub-drive circuit and the sub-light-emitting unit group having a same sequence number are electrically connected with each other, wherein i and j are positive integers greater than or equal to 1.

In some embodiments, at least one sub-drive circuit of the sub-drive circuits includes a drive circuit output point, and the sub-light-emitting units having different luminous colors in the at least one light-emitting unit group are electrically connected with different drive circuit output points respectively.

In some embodiments, at least one sub-drive circuit of the sub-drive circuits includes a drive circuit output point, and the sub-light-emitting units having a same luminous color in the light-emitting unit group are electrically connected with a same drive circuit output point.

In some embodiments, the first signal lines include first signal sub-lines and second signal sub-lines, and the first signal sub-lines and the second signal sub-lines are in different layers of the display panel.

In some embodiments, along a direction perpendicular to a plane of the display region, the display panel includes a base plate, a metal layer, a first planarization layer, the first signal sub-lines, a second planarization layer, the second signal sub-lines, a third planarization layer, the second signal lines and a first electrode layer which are sequentially stacked, where there is an overlapping region between an orthographic projection of the first signal sub-lines onto the plane of the display region and an orthographic projection of the second signal sub-lines onto the plane of the display region.

In some embodiments, the first planarization layer has a first via hole and a second via hole, the second planarization layer has a third via hole and a fourth via hole, and the third planarization layer has a fifth via hole and a sixth via hole;

where one end of the first signal sub-line is connected with the metal layer through the first via hole, and the other end of the first signal sub-line is connected with the second signal line through the third via hole and the fifth via hole;

where one end of the second signal sub-line is connected with the metal layer through the second via hole and the fourth via hole, and the other end of the second signal sub-line is connected with the second signal line through the sixth via hole.

In some embodiments, an orthographic projection of the second via hole onto a plate surface of the base plate at least partially overlaps an orthographic projection of the fourth via hole onto the plate surface of the base plate; and

an orthographic projection of the third via hole onto the plate surface of the base plate at least partially overlaps an orthographic projection of the fifth via hole onto the plate surface of the base plate.

In some embodiments, a side of the second planarization layer close to the base plate includes a stepped surface, a surface of the stepped surface close to the base plate is in contact with a surface of the metal layer away from the base plate, a seventh via hole is in a region of the second planarization layer close to the metal layer, and an eighth via hole is in the third planarization layer; and

one end of the second signal sub-line is connected with the metal layer through the seventh via hole, and the other end of the second signal sub-line is connected with the second signal line through the eighth via hole.

In some embodiments, a side of the third planarization layer close to the base plate includes a stepped surface, a surface of the stepped surface close to the base plate is in contact with the first signal sub-line, a ninth via hole is in a region of the third planarization layer close to the first signal sub-line, and a tenth via hole is in the first planarization layer; and

one end of the first signal sub-line is connected with the metal layer through the tenth via hole, and the other end of the first signal sub-line is connected with the second signal line through the ninth via hole.

In some embodiments, the first signal sub-line further includes a first transfer portion, a first transfer hole is provided in the second planarization layer, and the first transfer portion is connected with the second signal sub-line through the first transfer hole.

In some embodiments, the second signal sub-line further includes a second transfer portion, a second transfer hole is provided in the third planarization layer, and the second transfer portion is connected with the second signal line through the second transfer hole.

In some embodiments, a material of a first signal line is a transparent material;

In some embodiments, a material of a second signal line is a transparent material.

In some embodiments, the display panel further includes: a transition light-emitting unit group, second drive circuits, and transition signal lines. The transition light-emitting unit group is in the transition display region and includes transition light-emitting units; the second drive circuits are in the transition display region, and the second drive circuits are electrically connected with the transition light-emitting unit group; and the transition signal lines are between the second drive circuits and the transition light-emitting unit group to electrically connect the second drive circuits with the transition light-emitting unit group.

In some embodiments, there is an overlapping region between an orthographic projection of at least one drive circuit output point onto a plane of the transition display region and an orthographic projection of at least one of sub-light-emitting units of the transition light-emitting units onto the plane of the transition display region.

An embodiment of the present disclosure provides a display apparatus, which includes the display panel mentioned as above.

The present disclosure has the following beneficial effects.

The display region of the display panel provided by the present disclosure includes a first display region and a transition display region disposed adjacent to the first display region, and a transmittance of the first display region is greater than a transmittance of the transition display region. Different from the manner in which the drive circuits and the light-emitting units are electrically connected with each other one to one to achieve “one-to-one drive” in the prior arts, in the present disclosure, the drive circuits corresponding to the light-emitting units in the first display region are disposed outside, and multiple first drive circuits in the transition display region are electrically connected with multiple light-emitting units in multiple light-emitting unit groups in the first display region so as to drive two or more light-emitting units in the first display region by using one drive circuit in the transition display region, thus achieving the effect of “one driving two” and even “one driving more than two”, reducing the number of traces between the first display region and the transition display region and simplifying the trace layout. On the one hand, because the number of traces between the first display region and the transition display region is reduced, the crosstalk between signal lines is reduced accordingly. Thus, the sensitivity of the drive circuits driving the light-emitting units is improved, the image display distortion between pixels due to trace crosstalk is avoided, and the drive sensitivity and the display effect of the display panel are enhanced. On the other hand, two or more light-emitting units can be controlled by using one drive circuit, reducing the number of drive circuits in the display panel, lowering the material costs and process costs and turning on multiple homochromatic light-emitting units at the same time.

Furthermore, after the number of the traces is reduced, the transmittance of the first display region may be improved without reducing the pixel density of the screen, so as to improve the light transmission effect and display effect of the photosensitive elements in the first display region.

The additional aspects and advantages of the present disclosure will be partially given in the following descriptions and will become apparent from the following descriptions or be understood from the practice of the present disclosure.

### BRIEF DESCRIPTION OF DRAWINGS

The drawings herein incorporated into the specification and constituting a part of the specification illustrate the embodiments consistent with the present disclosure and interpret the principle of the present disclosure together with the specification.

FIGS. 1 to 5 are structural schematic diagrams illustrating a layout of a first display region at different positions on a display panel according to various embodiments of the present disclosure.

FIG. 6 is a schematic diagram illustrating a pixel arrangement at the time of arranging light-emitting units in a Chinese character triangle shape according to an embodiment of the present disclosure.

FIG. 7 is a schematic diagram illustrating a partial structure of a display panel at the time of arranging the light-emitting units based on the pixel arrangement of FIG. 6 according to an embodiment of the present disclosure.

FIG. 8 is a schematic diagram illustrating another partial structure of a display panel at the time of arranging light-emitting units based on the pixel arrangement of FIG. 6 according to an embodiment of the present disclosure.

FIG. 9 is a schematic diagram illustrating a pixel arrangement at the time of arranging light-emitting units in pentile according to an embodiment of the present disclosure.

FIG. 10 is a schematic diagram illustrating a partial structure of a display panel at the time of arranging light-emitting units based on the pixel arrangement of FIG. 8 according to an embodiment of the present disclosure.

FIGS. 11 to 18 are schematic diagrams of a partial structure of a display panel with different wiring manners according to various embodiments of the present disclosure.

FIGS. 19 to 24 are schematic sectional views of a display panel with different wiring manners according to various embodiments of the present disclosure.

FIG. 25 is a schematic diagram illustrating a drive circuit in a display panel according to the present disclosure.

Numerals of the drawings are described below:
101. first display region, 102. transition display region, 103. second display region, 104. non-display region;
1. light-emitting unit group, 11. first light-emitting unit, 12. second light-emitting unit;
110. first node, 120. second node, 130. third node;
2. first drive circuit, 201. first drive circuit output point, 3. first signal line, 31. first signal sub-line, 311. first transfer portion, 32. second signal sub-line, 321. second transfer portion, 4. second signal line, 5. second drive circuit, 501. second drive circuit output point, 502. transition signal line, 6. transition light-emitting unit group, 61. third light-emitting unit, 62. fourth light-emitting unit, 7. base plate, 8. metal layer, 9. first electrode layer, 100. first planarization layer, 1001. first via hole, 1002. second via hole, 1003. seventh via hole, 1004. tenth via hole, 200. second planarization layer, 2001. third via hole, 2002. fourth via hole, 2003. first transfer hole, 300. third planarization layer, 3001. fifth via hole, 3002. sixth via hole, 3003. eighth via hole, 3004. ninth via hole, 3005. second transfer hole.

### DETAILED DESCRIPTION

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

The terms used in the present disclosure are for the purpose of describing particular embodiments only, and are not intended to limit the present disclosure. Terms determined by “a”, “the” and “said” in their singular forms in the present disclosure and the appended claims are also intended to include plurality, unless clearly indicated otherwise in the context. It should also be understood that the term “and/or” as used herein refers to and includes any and all possible combinations of one or more of the associated listed items.

In the present disclosure, “electrical connection” includes connection of constituent elements through an element having an electric effect. “The element having an electric effect” is not specially limited as long as electric signals can be transmitted and received between the constituent elements connected hereby. “The element having an electric effect” may be, for example, an electrode or a wire or a switching element such as a transistor or the like, or another functional element such as a resistor, or an inductor or a capacitor or the like.

For those skilled in the arts, a pixel refers to a light-emitting unit of a display screen, and one pixel usually includes multiple subpixels of different colors. A pixel density (Pixels Per Inch, PPI) refers to the number of pixels in each inch of display screen. The higher the pixel density is, the higher the simulation degree is.

The full screen is a mainstream trend for development of the display screens. Nowadays, it is one of research hotspots for the current display panel manufacturers to find a method to achieve high-quality display of the camera region and its high transmittance at the time of shooting. The under-display camera technology refers to placing a camera under screen to ensure the display quality and shooting effect of the camera region without damaging the screen integrity, i.e. achieve high PPI. Today, there are three major under-display camera designing methods in the display panel industry. In a first method, the camera region is designed with low-density pixels and the pixel circuits for driving the pixels in the camera region to emit light are located in the camera region. In a second method, a transition region is included between the camera region and the display region, that is, the transition region is disposed between the camera region and the display region and at least partially surrounds the camera region. The camera region and the transition region are designed with low-density pixels and the pixel circuits for driving the pixels in the camera region to emit light are located in the transition region, and further, the pixel circuits and the light-emitting units in the camera region are connected with each other one to one by transparent traces. In a third method, the camera region and the display region outside the camera region are both designed with high-density pixel, the pixel circuits are all compressed and located in the display region outside the camera region, the light-emitting units are located in the camera region, and the pixel circuits and the light-emitting units are connected with each other one to one by transparent traces.

But, the common problems currently existing in the industry mainly come from two aspects: in a first aspect, in the current mainstream methods, the transmittance of the camera region is maximized by reducing the pixel density of the camera region or disposing the pixel circuits outside the camera region, but a problem of demarcation may arise from a difference between a display sharpness of the camera region and a display sharpness of the display region outside the camera region, reducing the display effect of the camera region. In a second aspect, when the pixel density of the camera region is not changed, the transmittance of the camera region is lower, reducing the shooting quality.

Therefore, it becomes a common difficulty for the industry to improve the display sharpness and transmittance of the under-display camera region.

A display panel and a display apparatus provided by the present disclosure aim to solve the above technical problems in the prior arts.

The embodiments of the present disclosure provide a display panel and a display apparatus. The display panel and the display apparatus in the embodiments of the present disclosure will be detailed below in combination with accompanying drawings. In a case of no conflicts, the features in the embodiments of the present disclosure can be mutually supplemented or combined.

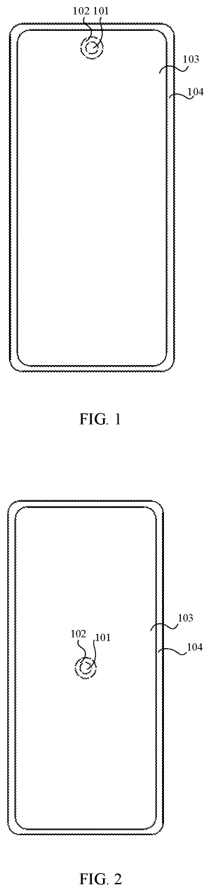

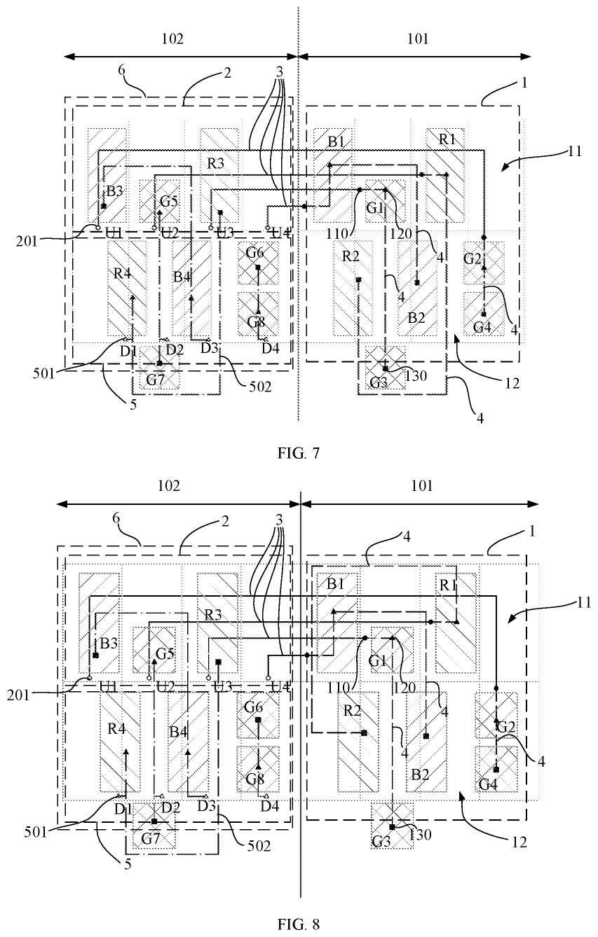

An embodiment of the present disclosure provides a display panel. As shown in FIGS. 1 to 5, a display region of the display panel includes a first display region 101, a transition display region 102, and a second display region 103. The transition display region 102 is located between the first display region 101 and the second display region 103. A transmittance of the first display region 101 is greater than a transmittance of the transition display region 102. As shown in FIG. 7 or 10, the display panel includes multiple light-emitting unit groups 1, multiple first drive circuits 2, multiple first signal lines 3, and multiple second signal lines 4. The light-emitting unit groups 1 are located in the first display region 101, and a light-emitting unit group 1 includes a first light-emitting unit 11 and a second light-emitting unit 12. The first drive circuits 2 are located in the transition display region 102 and are electrically connected with multiple light-emitting unit groups 1. The first signal lines 3 are disposed between the first drive circuits 2 and the first light-emitting units 11 to electrically connect the first drive circuits 2 with the first light-emitting units 11.

In this embodiment, the display region of the display panel includes a first display region 101, a transition display region 102, and a second display region 103. The transition display region 102 is located between the first display region 101 and the second display region 103. A transmittance of the first display region 101 is greater than a transmittance of the transition display region 102. Different from the manner in which the drive circuits and the light-emitting units are electrically connected with each other one to one to achieve “one-to-one drive” in the prior arts, in the present disclosure, the drive circuits corresponding to the light-emitting units in the first display region 101 are disposed outside, and the first drive circuits 2 in the transition display region 102 are electrically connected with the first light-emitting units 11, the second light-emitting units 12 and the like in the first display region 101 and thus two or more light-emitting units in the first display region 101 can be driven by the drive circuit in the transition display region 102 so as to achieve the effect of “one driving two” and even “one driving more than two”. In this way, the number of wires between the first display region 101 and the transition display region 102 can be reduced, simplifying the trace distribution and optimizing the under-display camera function. On the one hand, because the number of traces between the first display region 101 and the transition display region 102 is reduced, the crosstalk between signal lines is reduced accordingly. Thus, the sensitivity of the drive circuits driving the light-emitting units is improved, the image display distortion between pixels due to trace crosstalk is avoided, and the drive sensitivity and the display effect of the display panel are enhanced. On the other hand, two or more light-emitting units can be controlled by using one drive circuit or one drive circuit group, reducing the number of drive circuits in the display panel, lowering the material costs and process costs and turning on multiple homochromatic light-emitting units at the same time.

Furthermore, after the number of the traces is reduced, the transmittance of the first display region 101 may be improved without reducing the pixel density of the screen, so as to improve the light transmission effect and display effect of the photosensitive elements in the first display region 101.

It is to be noted that multiple light-emitting units may include two or more light-emitting units.

In some embodiments, the first display region 101 is a photosensitive element region of the display screen.

In some embodiments, the first display region 101 is an Under-Display Camera (UDC) region of the display screen.

In some embodiments, the transition display region 102 surrounds, or half surrounds or partially surrounds the first display region 101.

In some embodiments, the display panel further includes a non-display region 104 surrounding the display region. The first display region 101 may be disposed between the transition display region 102 and the non-display region 104, such that a partial outer edge of the first display region 101 is in contact with an inner edge of the non-display region 104. The partial edge may be at least part of any edge of the display panel.

In some embodiments, a photosensitive element may be disposed at a side of the first display region 101 of the display panel away from a light-emitting side of the display panel.

In some embodiments, an orthographic projection of the first display region 101 onto the panel surface of the display panel is greater than or equal to an orthographic projection of the photosensitive element onto the panel surface of the display panel.

In some embodiments, the orthographic projection of the first display region 101 onto the panel surface of the display panel is equal to the orthographic projection of the photosensitive element onto the panel surface of the display panel.

In some embodiments, a shape of the orthographic projection of the first display region 101 onto the display panel may be changed. For example, the orthographic projection of the first display region 101 onto the panel surface of the display panel is a circle, an ellipse, or a polygon such as triangle or pentagon. Those skilled in the arts may make selection based on actual circumstances, which is not specifically limited herein.

In some embodiments, the number of the first display regions 101 on the display panel may be changed. For example, there may be 1, 2, 3, 4, 5 . . . or n first display regions 101 on the display panel, where n is a positive integer.

In some embodiments, a size of the first display region 101 on the display panel may be changed. For example, the size of the first display region 101 may be 1/2.7 inches, 1/2.5 inches, 1/1.8 inches, or ⅔ inches or the like. The size of the first display region 101 may be adjusted based on the screen size of the display panel and the camera requirement, which is not specifically limited.

In some embodiments, a position of the first display region 101 on the display panel may be changed. For example, the first display region 101 may be disposed at the top, the bottom, the center, the upper left part, the upper right part, the lower left part or the lower right part of the display panel.

Illustratively, as shown in FIG. 1, the panel surface of the display panel is rectangle, the orthographic projection of the first display region 101 onto the panel surface of the display panel is circle, and the first display region 101 is disposed in the center of the top of the panel surface of the display panel.

Illustratively, as shown in FIG. 2, the panel surface of the display panel is rectangle, the orthographic projection of the first display region 101 onto the panel surface of the display panel is circle, and the first display region 101 is disposed in the center of the panel surface of the display panel.

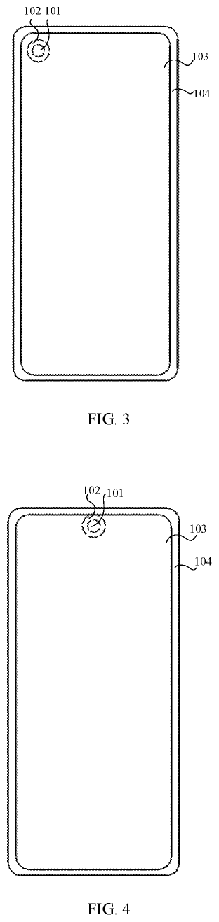

Illustratively, as shown in FIG. 3, the panel surface of the display panel is rectangle, the orthographic projection of the first display region 101 onto the panel surface of the display panel is circle, and the first display region 101 is disposed at the upper left corner of the panel surface of the display panel.

Illustratively, as shown in FIG. 4, the panel surface of the display panel is rectangle, the orthographic projection of the first display region 101 onto the panel surface of the display panel is circle, and an upper edge of the first display region 101 is overlapped with an inner edge of the non-display region 104.

Illustratively, the panel surface of the display panel is rectangle, the orthographic projection of the first display region 101 onto the panel surface of the display panel is circle, and two first display regions 101 are disposed in a row in the center of the top of the panel surface of the display panel.

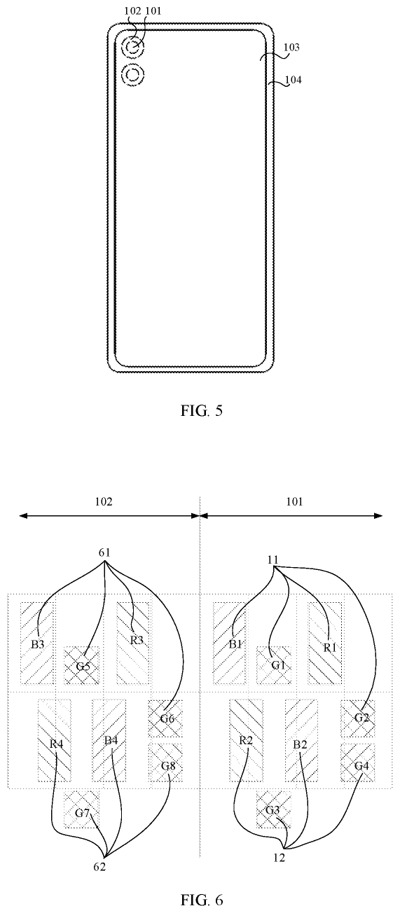

Illustratively, as shown in FIG. 5, the panel surface of the display panel is rectangle, the orthographic projection of the first display region 101 onto the panel surface of the display panel is circle, and two first display regions 101 are disposed in a column at the upper left corner of the panel surface of the display panel.

Illustratively, the panel surface of the display panel is rectangle, the orthographic projection of the first display region 101 onto the panel surface of the display panel is circle, and five first display regions 101 are disposed at four corners and the center of the display panel respectively.

In some embodiments, the light-emitting unit group 1 may include the first light-emitting unit 11 and the second light-emitting unit 12, where the number of the light-emitting units in the light-emitting unit group 1 may be n (n≥2), which is not limited herein.

In some embodiments, the light-emitting units in the light-emitting unit group 1 are arranged in a row or column.

In some embodiments, the light-emitting units in the light-emitting unit group 1 are arranged alternately and circularly.

In some embodiments, the light-emitting units in the light-emitting unit group 1 are arranged irregularly.

In some embodiments, the light-emitting unit group 1 may include the first light-emitting unit 11, the second light-emitting unit 12 and a third light-emitting unit (not shown). The second signal lines 4 are used to connect the first light-emitting unit 11 with the second light-emitting unit 12, and connect the second light-emitting unit 12 with the third light-emitting unit respectively.

In some embodiments, multiple light-emitting units included in the display region of the display panel are distributed alternately in odd rows and even rows. The light-emitting unit group 1 includes at least two light-emitting units respectively located in adjacent rows. The first drive circuit 2 is disposed in the same row as one of two light-emitting units located in adjacent rows in the light-emitting unit group 1. For example, two light-emitting units included in the light-emitting unit group 1 are respectively located in the m^{th} row and the (m+1)^{th} row, and the first drive circuit 2 may be located in the m^{th} row or the (m+1)^{th} row, where m is a positive integer greater than 0.

Illustratively, there are ten rows in the display region of the display panel. The first drive circuit 2 is disposed in the first row, and the first light-emitting unit 11 and the second light-emitting unit 12 are respectively disposed in the first and second rows. Furthermore, the first light-emitting unit 11 is disposed in the first row, and the second light-emitting unit 12 is disposed in the second row. The first drive circuit 2 is electrically connected with the first light-emitting unit 11 through the first signal lines 3, and the first light-emitting unit 11 is electrically connected with the second light-emitting unit 12 through the second signal lines 4.

Illustratively, there are ten rows in the display region of the display panel. The first drive circuit 2 is disposed in the second row, and the first light-emitting unit 11 and the second light-emitting unit 12 are jointly disposed in the first and second rows. Furthermore, the first light-emitting unit 11 is disposed in the second row, and the second light-emitting unit 12 is disposed in the first row. The first drive circuit 2 is electrically connected with the first light-emitting unit 11 through the first signal lines 3, and the first light-emitting unit 11 is electrically connected with the second light-emitting unit 12 through the second signal lines 4.

It can be known from the above embodiments that the light-emitting units and the drive circuits in the display panel are disposed in a same row or in adjacent rows to shorten the length of the signal lines between the drive circuits and the light-emitting units, reducing the crosstalk risk between the signal lines and lowering the material costs.

In some embodiments, the first drive circuit 2 and the light-emitting unit group 1 are located in two columns which are at least adjacent to reduce a distance between the first drive circuit 2 and the light-emitting unit group 1, further shortening the length of the first signal lines 3 and improving the sensitivity and display effect of the display panel.

Illustratively, the display region of the display panel has a 4*4 light-emitting unit array. The first display region 101 is disposed in the central 2*2 array region, the first drive circuit 2 is disposed at the position of the second row and the first column, the first light-emitting unit 11 is disposed at the position of the second row and the second column, and the second light-emitting unit 12 is disposed at the position of the third row and the second column. The first drive circuit 2 is electrically connected with the first light-emitting unit 11 through the first signal lines 3, and the first light-emitting unit 11 is electrically connected with the second light-emitting unit 12 through the second signal lines 4.

In some embodiments, each of at least one light-emitting unit includes multiple sub-light-emitting units, at least two of which have different luminous colors. The sub-light-emitting units with different luminous colors in the light-emitting unit group are electrically connected respectively via multiple second signal lines.

In some embodiments, each of at least one light-emitting unit includes multiple sub-light-emitting units. For example, the first light-emitting unit 11 and the second light-emitting unit 12 each include a first sub-light-emitting unit, a second sub-light-emitting unit, and a third sub-light-emitting unit. The first sub-light-emitting unit, the second sub-light-emitting unit and the third sub-light-emitting unit have different luminous colors. The first sub-light-emitting units, the second sub-light-emitting units and the third sub-light-emitting units in the light-emitting unit group are electrically connected respectively via multiple second signal lines 4.

In some embodiments, the first light-emitting unit 11 and the second light-emitting unit 12 each at least include a first sub-light-emitting unit, a second sub-light-emitting unit, and a third sub-light-emitting unit. The first drive circuits 2 are electrically connected with the sub-light-emitting units in multiple light-emitting unit groups 1 respectively through the first signal lines 3, and the sub-light-emitting units in the first light-emitting unit 11 are electrically connected with the sub-light-emitting units in the second light-emitting unit 12 respectively via the second signal lines 4. At least two types of sub-light-emitting units among the first sub-light-emitting units, the second sub-light-emitting units, and the third sub-light-emitting units have different luminous colors to satisfy different image display requirements.

Illustratively, the first light-emitting unit 11 and the second light-emitting unit 12 each at least include a first sub-light-emitting unit, a second sub-light-emitting unit, and a third sub-light-emitting unit. The first sub-light-emitting unit, the second sub-light-emitting unit, and the third sub-light-emitting unit of the first light-emitting unit 11 are electrically connected with the first sub-light-emitting unit, the second sub-light-emitting unit, and the third sub-light-emitting unit of the second light-emitting unit 12 respectively via the second signal lines 4. Thus, the first drive circuits 2 can achieve drive control indirectly on the second light-emitting units 12.

It should be noted that the first sub-light-emitting unit of the first light-emitting unit 11 is connected with the first sub-light-emitting unit of the second light-emitting unit 12, the second sub-light-emitting unit of the first light-emitting unit 11 is connected with the second sub-light-emitting unit of the second light-emitting unit 12, and the third sub-light-emitting unit of the first light-emitting unit 11 is connected with the third sub-light-emitting unit of the second light-emitting unit 12. Or, the first sub-light-emitting unit of the first light-emitting unit 11 is connected with the second sub-light-emitting unit of the second light-emitting unit 12, the second sub-light-emitting unit of the first light-emitting unit 11 is connected with the third sub-light-emitting unit of the second light-emitting unit 12, and the third sub-light-emitting unit of the first light-emitting unit 11 is connected with the first sub-light-emitting unit of the second light-emitting unit 12.

In some embodiments, the sub-light-emitting units included in the first light-emitting unit 11 are connected with the sub-light-emitting units emitting the same color in the second light-emitting unit 12 respectively.

In some embodiments, the first light-emitting unit 11 and the second light-emitting unit 12 each include a first sub-light-emitting unit, a second sub-light-emitting unit, a third sub-light-emitting unit and a fourth sub-light-emitting unit.

Illustratively, as shown in FIG. 6, the light-emitting units in the display panel are arranged in a Chinese character triangle shape. The first light-emitting unit 11 located in the first display region 101 includes four sub-light-emitting units R1, B1, G1 and G2, and the second light-emitting unit 12 includes four sub-light-emitting units R2, B2, G3 and G4. A transition light-emitting unit group 6 in the transition display region 102 includes a third light-emitting unit 61 and a fourth light-emitting unit 62, where the third light-emitting unit 61 includes four sub-light-emitting units R3, B3, G5 and G6, and the fourth light-emitting unit 62 includes four sub-light-emitting units R4, B4, G7 and G8.

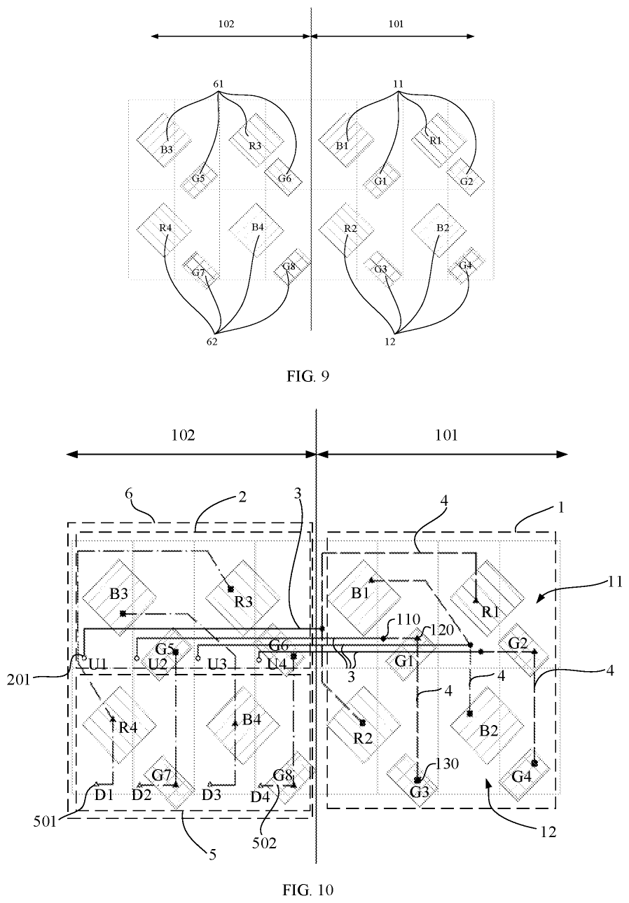

Illustratively, as shown in FIG. 9, the light-emitting units in the display panel are arranged in pentile. The first light-emitting unit 11 located in the first display region 101 includes four sub-light-emitting units R1, B1, G1 and G2, and the second light-emitting unit 12 includes four sub-light-emitting units R2, B2, G3 and G4. The transition light-emitting unit group 6 in the transition display region 102 includes a third light-emitting unit 61 and a fourth light-emitting unit 62, where the third light-emitting unit 61 includes four sub-light-emitting units R3, B3, G5 and G6, and the fourth light-emitting unit 62 includes four sub-light-emitting units R4, B4, G7 and G8.

In some embodiments, multiple first signal lines 3 are sequentially distributed on a plane of the display region, where the orthographic projections of multiple first signal lines 3 electrically connected with a same light-emitting unit group 1 onto the plane of the display region do not overlap.

In this embodiment, multiple first signal lines 3 are sequentially distributed on the plane of the display region, where the orthographic projections of multiple first signal lines 3 electrically connected with a same light-emitting unit group 1 onto the plane of the display region do not overlap. Thus, the use of a wiring region area of the display panel can be maximized while the first signal lines 3 are not intersected with each other. The reasonable layout of the trace space of the display panel can be achieved.

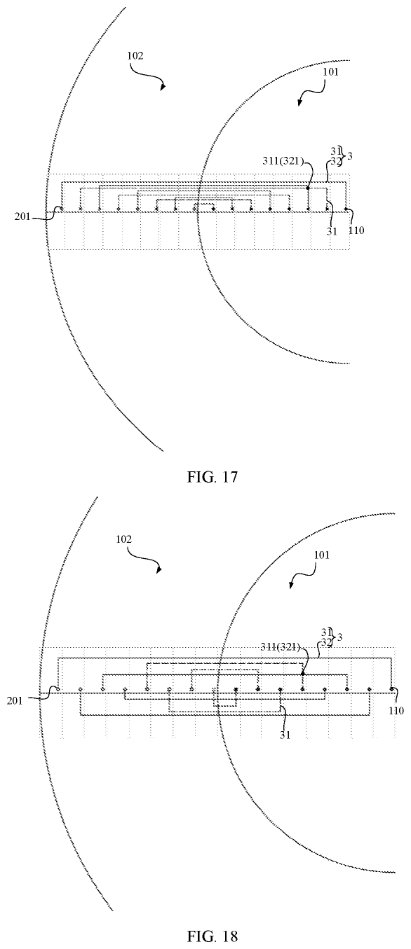

In some embodiments, as shown in FIGS. 17 and 18, there is an overlapping region between the orthographic projections of multiple first signal lines 3 onto the plane of the display region and the orthographic projections of multiple second signal lines 4 onto the plane of the display region.

It can be known from the above embodiments that in a space perpendicular to the display region, the first signal lines 3 and the second signal lines 4 are not overlapped, and thus the orthographic projections of the first signal line 3 and the second signal line 4 onto the plane of the display region can be intersected or overlapped. While the crosstalk between the signal lines can be reduced, the wiring limitation of the first signal lines 3 and the second signal lines 4 in the film layers of the display panel can be diminished.

In some embodiments, the orthographic projections of the first signal lines 3 onto the plane of the display region intersect with the orthographic projection of a first demarcation line onto the plane of the display region, and the first signal lines 3 are sequentially distributed along an extension direction of the first demarcation line. The first demarcation line is a demarcation line between the first display region 101 and the transition display region 102.

It should be noted that the first demarcation line is a peripheral line of the first display region 101.

Illustratively, the first display region 101 is a circle, and thus the first demarcation line is a circumferential line of the first display region 101 and the direction of the first demarcation line is a clockwise direction along the circumferential line or a counterclockwise direction along the circumferential line.

Illustratively, the first display region 101 is a square, and thus the first demarcation line is a closed folding line of four sides of the first display region 101, and the direction of the first demarcation line is a direction of four sides.

In some embodiments, as shown in FIG. 7, the sub-light-emitting units in the first light-emitting unit 11 and the second light-emitting unit 12 are arranged in a Chinese character triangle shape, and the first drive circuit 2 includes four first drive circuit output points 201, which are U1, U2, U3 and U4 shown by hollow dots in FIG. 7, where the distances of the U1, U2, U3 and U4 from the first demarcation line sequentially decrease. In FIG. 7, the solid lines refer to the first signal lines 3, and the dashed lines refer to the second signal lines 4. U1, G2 and G4 are electrically connected with each other by the first signal line 3 and the second signal line 4, U2, R1 and R2 are electrically connected with each other by the first signal line 3 and the second signal line 4, U3, G1 and G3 are electrically connected with each other by the first signal line 3 and the second signal line 4, and U4, B1 and B2 are electrically connected with each other by the first signal line 3 and the second signal line 4.

In some embodiments, as shown in FIG. 8, a wiring method of the second signal lines 4 different from FIG. 7 is provided. It is noted that the wiring method of the second signal lines 4 are not limited in the present disclosure and those skilled in the arts can make selection based on actual situations.

In some embodiments, as shown in FIG. 10, the sub-light-emitting units in the first light-emitting unit 11 and the second light-emitting unit 12 are arranged in pentile, and the first drive circuit 2 includes four first drive circuit output points 201, which are U1, U2, U3 and U4 shown by hollow dots in FIG. 10, where the distances of the U1, U2, U3 and U4 from the first demarcation line sequentially decrease. In FIG. 7, the solid lines refer to the first signal lines 3, and the dashed lines refer to the second signal lines 4. U1, G2 and G4 are electrically connected with each other by the first signal line 3 and the second signal line 4, U2, R1 and R2 are electrically connected with each other by the first signal line 3 and the second signal line 4, U3, G1 and G3 are electrically connected with each other by the first signal line 3 and the second signal line 4, and U4, B1 and B2 are electrically connected with each other by the first signal line 3 and the second signal line 4. It should be noted that those skilled in the arts make selection on the pixel arrangement methods based on actual circumstances, which is not limited herein.

In some embodiments, the first drive circuit 2 includes multiple sub-drive circuits, and each sub-drive circuit includes one first drive circuit output point 201. Multiple first signal lines 3 are respectively connected with the first drive circuit output points 201 of the multiple sub-drive circuits, so as to achieve electrical connection with the light-emitting units in multiple light-emitting unit groups 1. Illustratively, each light-emitting unit in multiple light-emitting unit groups 1 at least includes multiple sub-light-emitting units, and the sub-light-emitting units connected with a same sub-drive circuit have the same luminous color.

In some embodiments, as shown in FIG. 7 or 10, the transition light-emitting unit group 6 in the transition display region 102 includes a third light-emitting unit 61 and a fourth light-emitting unit 62. The third light-emitting unit 61 includes four sub-light-emitting units R3, B3, G5 and G6, and the fourth light-emitting unit 62 includes four sub-light-emitting units R4, B4, G7 and G8. A second drive circuit 5 includes four second drive circuit output points 501, which are D1, D2, D3 and D4 shown by hollow dot-shaped triangles in FIGS. 7 and 10. In the FIG, the dot-dash lines are transition signal lines 502. D1, R3 and R4 are electrically connected with each other by the first signal line 3 and the second signal line 4, D2, G5 and G7 are electrically connected with each other by the first signal line 3 and the second signal line 4, D3, B3 and B4 are electrically connected with each other by the first signal line 3 and the second signal line 4, and D4, G6 and G8 are electrically connected with each other by the first signal line 3 and the second signal line 4.

In some embodiments, the shape of the orthographic projection of the first signal line 3 onto the plane of the display region may be straight line, folding line, arc-shaped line, or wave-like line or the like, which is not limited herein.

In some embodiments, the sub-light-emitting units having the same luminous color in a same light-emitting unit group may be electrically connected with each other via one second signal line 4.

In this embodiment, the sub-light-emitting units having the same luminous color in a same light-emitting unit group are connected with each other via the second signal line, namely, one end of the second signal line is connected with one sub-light-emitting unit in one light-emitting unit group and the other end of the second signal line is connected with a sub-light-emitting unit having the same luminous color as the one sub-light-emitting unit in the same light-emitting unit group.

In some embodiments, the orthographic projections of multiple second signal lines onto the plane of the display region do not overlap.

In this embodiment, no overlap of the orthographic projections of multiple second signal lines onto the plane of the display region can avoid poor display effect arising from the crosstalk between the signal lines.

In some embodiments, multiple first drive circuits are sequentially arranged as a first, second, third . . . and m^{th} drive circuits along a direction away from the first display region, multiple light-emitting unit groups are sequentially arranged as a first, second, third . . . and n^{th} light-emitting unit groups along a direction away from the transition display region, and the drive circuit and the light-emitting unit group having a same sequence number are electrically connected with each other, where m and n are positive integers greater than or equal to 1.

It should be noted that m may be equal to n. Those skilled in the arts may set m and n based on actual situations, which is not limited herein.

In some embodiments, the light-emitting units included in the n^{th} light-emitting unit group electrically connected with the m^{th} drive circuit are distributed alternately in rows, where the m^{h} drive circuit is disposed in the same row as at least one of the light-emitting units included in the n^{h} light-emitting unit group.

In this embodiment, the m^{th} drive circuit is disposed in the same row as at least one of the light-emitting units included in the n^{th} light-emitting unit group such that the distance between the drive circuit and the light-emitting unit group can be shortened, reducing the length of the traces and rationalizing the space layout.

In some embodiments, each of at least one first drive circuit 2 includes multiple sub-drive circuits which are sequentially arranged as a first, second, third . . . and i^{th} sub-drive circuits along a direction away from the first display region; the sub-light-emitting units included in the light-emitting unit disposed in the same row as the multiple sub-drive circuits are sequentially arranged as a first, second, third . . . and j^{th} sub-light-emitting units along a direction away from the transition display region; the sub-drive circuit and the sub-light-emitting unit group having a same sequence number are electrically connected with each other, where i and j are positive integers greater than or equal to 1.

It should be noted that i may be equal to j. Those skilled in the arts may set i and j based on actual situations, which is not limited herein.

In some embodiments, each of at least one sub-drive circuit includes one drive circuit output point, and the sub-light-emitting units having different luminous colors in the light-emitting unit group are electrically connected with different drive circuit output points respectively.

In some embodiments, each of at least one sub-drive circuit includes one drive circuit output point, and the sub-light-emitting units having a same luminous color in the light-emitting unit group are electrically connected with a same drive circuit output point respectively.

In this embodiment, the sub-light-emitting units having a same luminous color are connected with a same drive circuit output point, such that multiple sub-light-emitting units having a same luminous color are controlled to be luminous or not at the same time by a same drive circuit.

It should be noted that the drive circuit output points include the first drive circuit output points 201 and the second drive circuit output points 501.

In some embodiments, the first signal lines 3 may be disposed in an odd or even row, and the first drive circuit 2 may be in the same row as the first signal lines 3 or disposed in a row adjacent to the row where the first signal lines 3 are located.

In some embodiments, some of the first signal lines 3 are disposed in an odd row of light-emitting units and some of the first signal lines 3 are disposed in an even row of light-emitting units. At this time, the first drive circuit 2 is disposed in the odd row or even row of light-emitting units.

Illustratively, four first signal lines 3 are connected between the first drive circuit 2 and the first light-emitting unit 11, where two first signal lines 3 are disposed respectively in an odd row and even row of light-emitting units.

Illustratively, three first signal lines 3 are connected between the first drive circuit 2 and the first light-emitting unit 11, and these three first signal lines 3 are all distributed in an odd row or even row of light-emitting units where the first drive circuit 2 is located.

Illustratively, three first signal lines 3 are connected between the first drive circuit 2 and the first light-emitting unit 11, where two first signal lines 3 are distributed in the odd row of light-emitting units or the even row of light-emitting units where the first drive circuit 2 is located, and the other one first signal line 3 is located in the even row of light-emitting units or the odd row of light-emitting units adjacent to the first drive circuit 2.

It can be known from the above embodiments that some first signal lines 3 and the remaining first signal lines 3 are respectively distributed in two adjacent rows, such that the first signal lines 3 are more uniformly distributed in the display region, increasing the spacing between the first signal lines 3, avoiding the crosstalk between the signal lines, and improving the conduction yield.

In some embodiments, the first sub-light-emitting unit, the second sub-light-emitting unit and the third sub-light-emitting unit emit the light of one color of three colors respectively, where the three colors include red, green and blue. The second signal lines 4 are used to connect at least two monochromatic sub-light-emitting units between the first light-emitting unit 11 and the second light-emitting unit 12.

Illustratively, the first light-emitting unit 11 and the second light-emitting unit 12 each include a first sub-light-emitting unit, a second sub-light-emitting unit and a third sub-light-emitting unit, where the first sub-light-emitting unit emits red (R) light, the second sub-light-emitting unit emits green (G) light, and the third sub-light-emitting unit emits blue (B) light. The first sub-light-emitting unit of the first light-emitting unit 11 is connected with the first sub-light-emitting unit of the second light-emitting unit 12 via the second signal line 4, the second sub-light-emitting unit of the first light-emitting unit 11 is connected with the second sub-light-emitting unit of the second light-emitting unit 12 via the second signal line 4, and the third sub-light-emitting unit of the first light-emitting unit 11 is connected with the third sub-light-emitting unit of the second light-emitting unit 12 via the second signal line 4.

In an example, the first light-emitting unit 11 and the second light-emitting unit 12 each further include a fourth sub-light-emitting unit, where the fourth sub-light-emitting unit emits white (W) light. The fourth sub-light-emitting unit of the first light-emitting unit 11 is connected with the fourth sub-light-emitting unit of the second light-emitting unit 12 via the second signal line 4.

In some embodiments, the shape of each sub-light-emitting unit may be a circle, an ellipse, or a polygon such as rectangle, rhombus, pentagon, hexagon or the like.

In some embodiments, when the first light-emitting unit 11 or the second light-emitting unit 12 includes three sub-light-emitting units, these three sub-light-emitting units may be arranged horizontally, vertically or in a Chinese character triangle shape. When the first light-emitting unit 11 or the second light-emitting unit 12 includes four sub-light-emitting units, these four sub-light-emitting units may be arranged horizontally, vertically or in square. No special limitation is made in the present disclosure.

In some embodiments, the first signal lines include first signal sub-lines 31 and second signal sub-lines 32, where the first signal sub-lines 31 and the second signal sub-lines 32 are located respectively in different layers of the display panel.

It can be known from the above embodiments that the first signal lines 3 include the first signal sub-lines 31 and the second signal sub-lines 32 which are respectively disposed in two film layers of the display panel to further use the space in the film layer. Compared with disposal of the first signal lines 3 in only one film layer, the disposal of the first signal lines 3 in two film layers can further use the height space perpendicular to the panel surface of the display panel in the display panel in addition to using the plane space of the panel surface of the display panel.

In some embodiments, one end of the first signal sub-lines 31 and one end of the second signal sub-lines 32 are both electrically connected with corresponding first drive circuit output point 201 of the first drive circuits 2, and the other end of the first signal sub-lines 31 and the other end of the second signal sub-lines 32 are both electrically connected with corresponding first node 110 (a first electrode conduction point) in the multiple light-emitting unit groups.

In some embodiments, along a direction perpendicular to the plane of the display region, the display panel includes a base plate 7, a metal layer 8, a first planarization layer 100, a first signal sub-line 31, a second planarization layer 200, a second signal sub-line 32, a third planarization layer 300, a second signal line 4, and a first electrode layer 9, which are sequentially stacked. There is an overlapping region between an orthographic projection of the first signal sub-lines 31 onto the plane of the display region and an orthographic projection of the second signal sub-lines 32 onto the plane of the display region.

It can be known from the above embodiments that the first signal sub-lines 31 and the second signal sub-lines 32 are located in two different film layers. Therefore, their orthographic projections onto the plane of the display region may be overlapped or intersected, which reduces the crosstalk between the signal lines and diminishes the wiring limitation of the first signal sub-lines 31 and the second signal sub-lines 32 in the film layer of the display panel.

In some embodiments, the base plate 7 is a rigid base plate 7 or flexible base plate 7, which may be made from silicon, glass or Liquid Crystal Polymer (LCP). Those skilled in the arts can make selection on the material of the base plate 7 based on actual design requirements, which is not specially limited in the present disclosure.

Illustratively, the material of the base plate 7 is glass.

In some embodiments, the first electrode layer 9 may include a high-work-function material. When the first electrode layer is used for bottom emission structure, the first electrode layer may be made from a transparent conductive oxide material such as Indium Tin Oxide (ITO), Indium Zinc Oxide (IZO) or Indium Gallium Zinc Oxide (IGZO), with a thickness in a range of 80 nm to 200 nm. When the first electrode layer is used for top emission structure, the first electrode layer may be made from a composite structure of a transparent oxide layer such as Ag/ITO or Ag/IZO.

Illustratively, the material of the first electrode layer 9 is ITO.

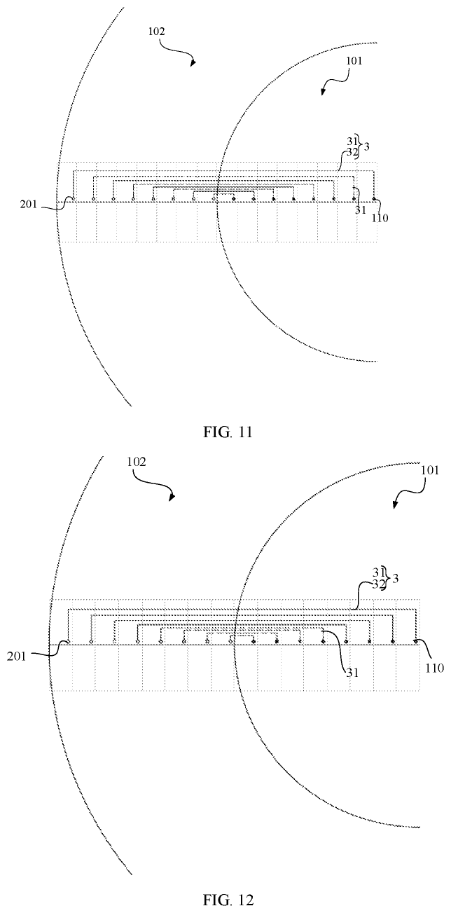

In some embodiments, as shown in FIGS. 11 and 14, the first signal sub-lines 31 and the second signal sub-lines 32 are alternately distributed along the direction of the first demarcation line.

Illustratively, the signal lines are uniformly distributed in parallel, and thus a spacing between a first signal sub-line 31 and a second signal sub-line 32 adjacent to the first signal sub-line 31 is calculated in the formula D1=Sqrt (X₁²+Y₁²), where Sqrt refers to a square root of a non-negative real number, X₁ refers to a spacing between the first signal sub-line 31 and the adjacent second signal sub-line 32 along the direction parallel to the base plate 7, and Y₁ is a spacing between the first signal sub-line 31 and the adjacent second signal sub-line 32 along the direction perpendicular to the base plate 7. Therefore, the alternate distribution of the first signal sub-lines 31 and the second signal sub-lines 32 in the two film layers can further increase the spatial distance between the first signal lines 3, avoiding the crosstalk between the signal lines.

Illustratively, as shown in FIG. 11, the first signal lines 3 include four first signal sub-lines 31 and four second signal sub-lines 32; along the extension direction of the first demarcation line, eight first signal lines 3 are sequentially distributed, where the first, third, fifth, and seventh lines are first signal sub-lines 31 and the second, fourth, sixth and eighth lines are second signal sub-lines 32.

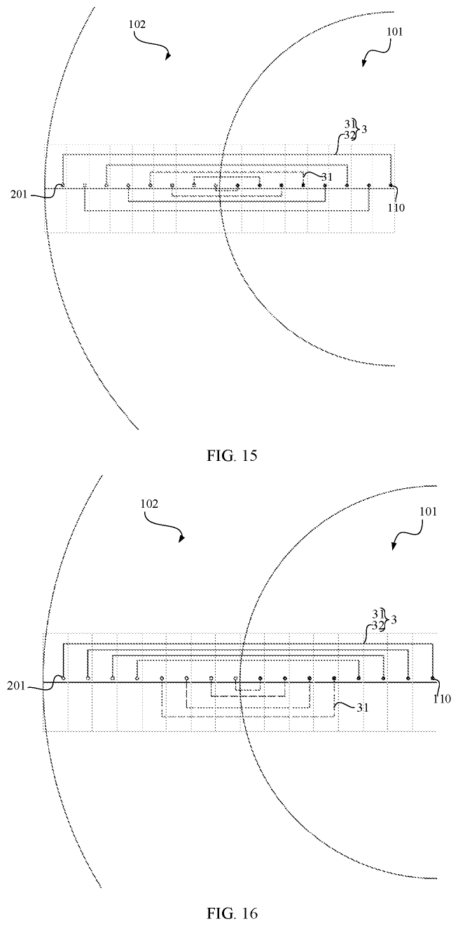

In some embodiments, at least part of the first signal sub-lines 31 are continuously distributed along the extension direction of the first demarcation line, as shown in FIG. 15.

In some embodiments, at least part of the second signal sub-lines 32 are continuously distributed along the extension direction of the first demarcation line.

In some embodiments, the first signal sub-lines 31 and the second signal sub-lines 32 are continuously distributed along the extension direction of the first demarcation line respectively, as shown in FIGS. 12, 13 and 16.

Illustratively, as shown in FIG. 12, the first signal lines 3 include four first signal sub-lines 31 and four second signal sub-lines 32. Along the direction of the first demarcation line, four first signal sub-lines 31 are sequentially and continuously distributed and then four second signal sub-lines 32 are sequentially and continuously distributed. The signal lines are uniformly distributed in parallel, and a spacing between adjacent first signal sub-line 31 and second signal sub-line 32 along a direction of the plate surface of the base plate 7 is Δd₁. The orthographic projections of the first signal sub-lines 31 along the direction perpendicular to the base plate 7 are overlapped, and the orthographic projections of the second signal sub-lines 32 along the direction perpendicular to the base plate 7 are overlapped. A spacing between the first signal sub-lines 31 and the second signal sub-lines 32 along the direction perpendicular to the plate surface of the base plate 7 is Δd₂. Thus, a spacing between the first signal sub-line 31 and the second signal sub-line 32 which are most distant from each other is D2=Sqrt[(7Δd₁)²+(Δd₂)²]. It can be known that in this manner, the first signal sub-lines 31 and the second signal sub-lines 32 will be more independent of each other and will have a larger spacing, reducing the possibility of crosstalk.

In some embodiments, at least part of the first signal sub-lines 31 and/or at least part of the second signal sub-lines 32 are disposed in an even row or odd row where the light-emitting unit is located.

Illustratively, all the first signal sub-lines 31 are distributed in an odd row of light-emitting units, and all the second signal sub-lines 32 are distributed in an even row of light-emitting units. In this distribution manner, it is assumed that there are 2 m first signal lines 3 including m first signal sub-lines 31 and m second signal sub-lines 32. Compared with the distribution manner in which the first signal lines 3 are all distributed in the odd row or even row of light-emitting units, the first signal lines 3 are disposed in different zones, that is, m first signal sub-lines 31 are all distributed in the odd row of light-emitting units, and m second signal sub-lines 32 are all distributed in the even row of light-emitting units, such that the first signal lines 3 can be reduced by half in a same zone, reducing the risk of signal line crosstalk and increasing the signal conduction yield.

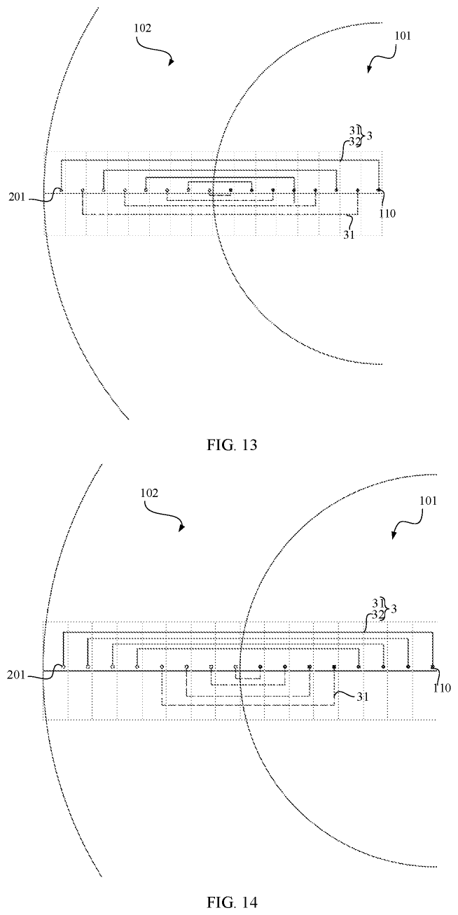

Illustratively, as shown in FIG. 13, the first signal lines 3 include four first signal sub-lines 31 and four second signal sub-lines 32, where the first signal sub-lines 31 are all distributed in an odd row of light-emitting units and the second signal sub-lines 32 are all distributed in an adjacent even row of light-emitting units.

Illustratively, as shown in FIG. 14, the first signal lines 3 include four first signal sub-lines 31 and four second signal sub-lines 32, where two first signal sub-lines 31 and two second signal sub-lines 32 are distributed in an odd row of light-emitting units, and the remaining two first signal sub-lines 31 and two second signal sub-lines 32 are distributed in an adjacent even row of light-emitting units.

In some embodiments, at least part of the orthographic projection of the first signal sub-line 31 onto the plane of the display region is not overlapped with the orthographic projection of the second signal sub-line 32 onto the plane of the display region.

It can be known from the above embodiments that, as shown in FIGS. 11 to 16, the orthographic projections of the first signal sub-lines 31 and the second signal sub-lines 32 onto the plate surface of the base plate 7 (the plane of the display region) are not overlapped, which largely reduces the crosstalk between adjacent signal lines, and improving the yield of the display panel.

In the present disclosure, the first signal sub-line 31 is electrically connected with the metal layer 8 by penetrating through a via hole of an insulation film layer between the first signal sub-line 31 and the metal layer 8, while the first signal sub-line 31 is electrically connected with the second signal line 4 by penetrating through a via hole of an insulation film layer between the first signal sub-line 31 and the second signal line 4. Similarly, the second signal sub-line 32 is electrically connected with the metal layer 8 by penetrating through a via hole of an insulation film layer between the second signal sub-line 32 and the metal layer 8, while the second signal sub-line 32 is electrically connected with the second signal line 4 by penetrating through a via hole of an insulation film layer between the second signal sub-line 32 and the second signal line 4. The via holes in the insulation film layers can be disposed in the four non-limiting implementations exemplified below. Based on the actual process requirements, the first signal sub-lines 31 and the second signal sub-lines 32 may also be electrically connected with the metal layer 8 and the second signal lines 4 respectively in a different manner.

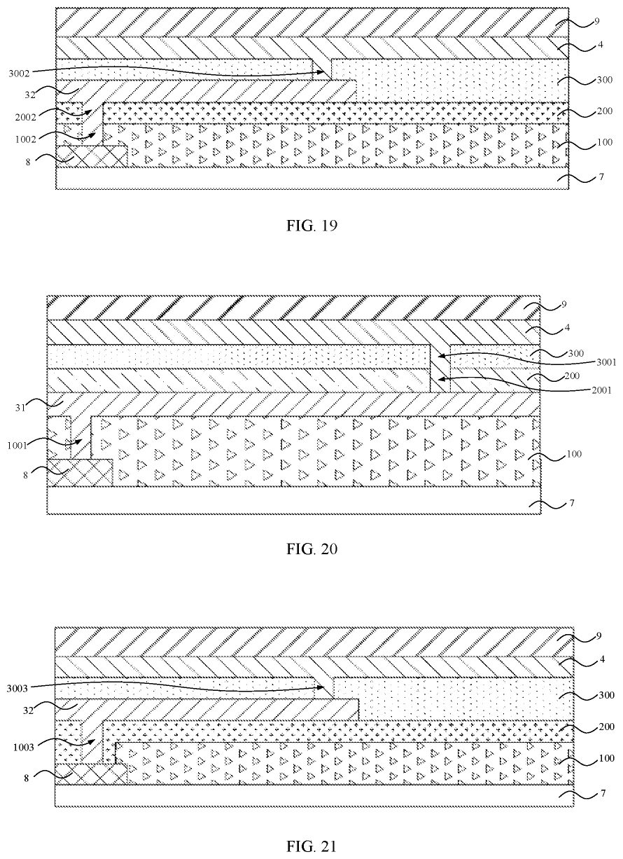

In a first implementation, as shown in FIGS. 19 and 20, the first planarization layer 100 has a first via hole 1001 and a second via hole 1002, the second planarization layer 200 has a third via hole 2001 and a fourth via hole 2002, and the third planarization layer 300 has a fifth via hole 3001 and a sixth via hole 3002. One end of the first signal sub-line 31 is connected with the metal layer 8 through the first via hole 1001, and the other end of the first signal sub-line 31 is connected with the second signal line 4 through the third via hole 2001 and fifth via hole 3001. One end of the second signal sub-line 32 is connected with the metal layer 8 through the second via hole 1002 and the fourth via hole 2002, and the other end of the second signal sub-line 32 is connected with the second signal line 4 through the sixth via hole 3002.

It can be known from the above embodiments that the first signal sub-line 31 is connected with the metal layer 8 and the second signal line 4 respectively through the first via hole 1001, the third via hole 2001 and the fifth via hole 3001, and the second signal sub-line 32 is connected with the metal layer 8 and the second signal line 4 respectively through the second via hole 1002, the fourth via hole 2002 and the sixth via hole 3002. The second signal lines 4 are connected with the first electrode layer 9, and the first signal sub-lines 31 and the second signal sub-lines 32 are electrically connected with respective first electrodes of the first light-emitting unit 11 through different via holes, so as to achieve electrical connection between the first drive circuit 2 and the first light-emitting unit 11.

It should be noted that since the first signal sub-lines 31 do not intersect with the second signal sub-lines 32 in a film layer space, FIGS. 19 and 20 respectively show a sectional view of a film layer where the first signal sub-line 31 is located and a sectional view of a film layer where the second signal sub-line 32 at a different position is located.

In some embodiments, an orthographic projection of the second via hole 1002 onto the plate surface of the base plate 7 is at least partially overlapped with an orthographic projection of the fourth via hole 2002 onto the plate surface of the base plate 7; an orthographic projection of the third via hole 2001 onto the plate surface of the base plate 7 is at least partially overlapped with an orthographic projection of the fifth via hole 3001 onto the plate surface of the base plate 7. Thus, the first signal sub-lines 31 and the second signal sub-lines 32 can smoothly pass through the via holes and further to communicate with the second signal lines 4.

Illustratively, the orthographic projection of the second via hole 1002 onto the plate surface of the base plate 7 is fully overlapped with the orthographic projection of the fourth via hole 2002 onto the plate surface of the base plate 7; and the orthographic projection of the third via hole 2001 onto the plate surface of the base plate 7 is fully overlapped with the orthographic projection of the fifth via hole 3001 onto the plate surface of the base plate 7.

Illustratively, the orthographic projection of the second via hole 1002 onto the plate surface of the base plate 7 is overlapped by 50% in area with the orthographic projection of the fourth via hole 2002 onto the plate surface of the base plate 7; and the orthographic projection of the third via hole 2001 onto the plate surface of the base plate 7 is overlapped by 50% in area with the orthographic projection of the fifth via hole 3001 onto the plate surface of the base plate 7.

In a second implementation, as shown in FIG. 21, a stepped surface is formed at a side of the second planarization layer 200 close to the base plate 7, and a surface of the stepped surface close to the base plate 7 is in contact with a surface of the metal layer 8 away from the base plate 7; a seventh via hole 1003 is provided in a region of the second planarization layer 200 close to the metal layer 8, and an eighth via hole 3003 is provided in the third planarization layer 300.

One end of the second signal sub-line 32 is connected with the metal layer 8 through the seventh via hole 1003 and the other end of the second signal sub-line 32 is connected with the second signal line 4 through the eighth via hole 3003.

It can be known from the above embodiments that the second via hole 1002 and the fourth via hole 2002 in the first implementation are combined into the seventh via hole 1003, and a part of the second planarization layer 200 and a part of the first planarization layer 100 in the original position are combined and jointly deposited with a same material. In a first aspect, since an inter-layer void formed by deposition with different materials is removed by deposition with a same material, a depth of the seventh via hole 1003 in a direction perpendicular to the base plate 7 in FIG. 21 is slight less than a sum of the depths of the second via hole 1002 and the fourth via hole 2002 shown in FIGS. 19 to 20, which further shortens the trace length of the signal lines in the display panel, reducing the material costs and improving the electric conduction capability. In a second aspect, the second via hole 1002 and the fourth via hole 2002 are combined integrally to prevent the process for forming the via holes separately from affecting the final electric conduction effect, thus improving the electric conduction capability. In a third aspect, a part of the second planarization layer 200 and a part of the third planarization layer 300 are combined and jointly deposited with a same material, which avoids the trouble of using an adhesive to bond two layers formed by separate depositions and also avoids the influence on the signal lines due to relative displacement of the via holes arising from failure of the adhesive between two layers, thus avoiding affecting the electric conduction capability. Therefore, the control sensitivity of the first drive circuits 2 on the light-emitting units is increased.

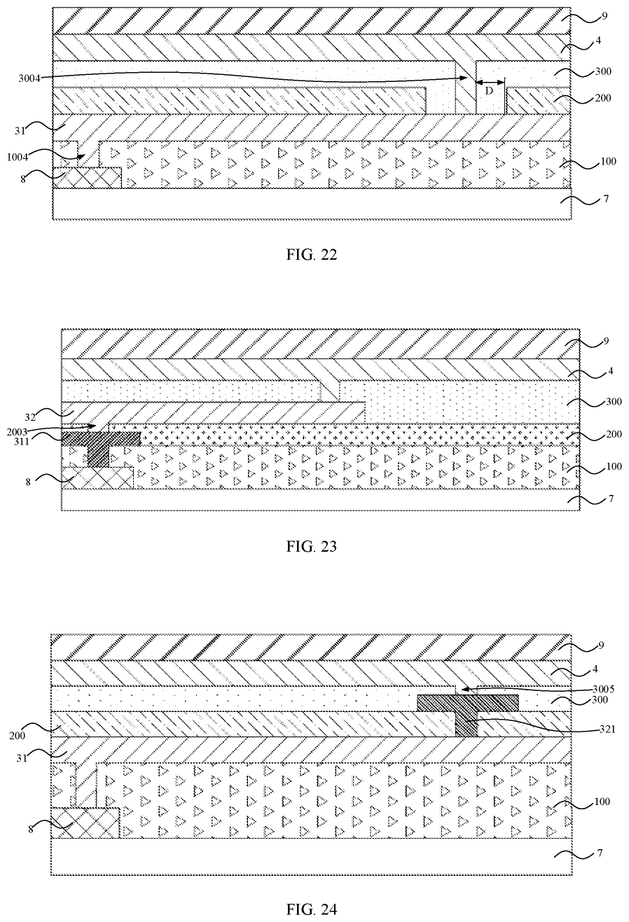

In a third implementation, as shown in FIG. 22, a stepped surface is formed at a side of the third planarization layer 300 close to the base plate 7, and a surface of the stepped surface close to the base plate 7 is in contact with the first signal sub-lines 31; a ninth via hole 3004 is provided in a region of the third planarization layer 300 close to the first signal sub-lines 31, and a tenth via hole 1004 is provided in the first planarization layer 100.

One end of the first signal sub-line 31 is connected with the metal layer 8 through the tenth via hole 1004, and the other end of the first signal sub-line 31 is connected with the second signal line 4 through the ninth via hole 3004.

In the above embodiments, the third via hole 2001 and the fifth via hole 3001 in the second implementation are combined into the ninth via hole 3004, and a part of the second planarization layer 200 and a part of the third planarization layer 300 are combined and jointly deposited with a same material. Its principle and beneficial effect are similar to the second implementation and will not be repeated herein.

In a fourth implementation, as shown in FIGS. 21 to 22, the via hole opening manners of FIGS. 21 and 22 are combined. A stepped surface is formed at a side of the second planarization layer 200 close to the base plate 7 and a surface of the stepped surface close to the base plate 7 is in contact with a surface of the metal layer 8 away from the base plate 7; a seventh via hole 1003 is provided in a region of the second planarization layer 200 close to the metal layer 8 and an eighth via hole 3003 is provided in the third planarization layer 300. One end of the second signal sub-line 32 is connected with the metal layer 8 through the seventh via hole 1003 and the other end is connected with the second signal line 4 through the eighth via hole 3003. A stepped surface is formed at a side of the third planarization layer 300 close to the base plate 7 and a surface of the stepped surface close to the base plate 7 is in contact with the first signal sub-line 31; a ninth via hole 3004 is provided in a region of the third planarization layer 300 close to the first signal sub-line 31 and a tenth via hole 1004 is provided in the first planarization layer 100. One end of the first signal sub-line 31 is connected with the metal layer 8 through the tenth via hole 1004 and the other end is connected with the second signal line 4 through the ninth via hole 3004.

In this embodiment, the second implementation and the third implementation are combined and its principle and beneficial effects are similar to the second implementation, and will not be repeated herein.

In some embodiments, in the second, third or fourth implementation, a spacing between a corner of the stepped surface and an adjacent via hole is greater than or equal to 3 microns. As shown in FIG. 22, D≥3 μm. In this way, electrical conduction between the first signal lines 3 and the second signal lines 4 can be achieved through the via holes.

In some embodiments, the spacing D between the comer of the stepped surface and the adjacent via hole may be equal to 3 microns, 6 microns, 10 microns, 15 microns or 20 microns or the like. Those skilled in the arts can carry out design based on actual circumstances, and no limitation is made herein.

In an example, a stepped surface is located respectively at both sides of each via hole, and the spacings between the corners of the stepped surfaces at both sides and both sides of the via hole are both 5 microns.

In some embodiments, an angle of the corner of the stepped surface is α, 0<α<180°.

In an example, the angle of the comer of the stepped surface is α, α=90°.

In some embodiments, a surface of the stepped surface close to the via hole is a straight surface.

In some embodiments, the surface of the stepped surface close to the via hole is a serrated or wavy surface, which can further improve an attachment degree between the planarization layers, and prevent relative displacement between the film layers, so as to increase the stability of the display panel and prolong the fatigue life.

In some embodiments, an orthographic projection of each via hole on the panel surface of the display panel may be a circle, an ellipse, or a polygon such as triangle or pentagon. Those skilled in the arts can make selection based on actual situations and no specific limitation is made herein.

In an example, the orthographic projection of each via hole onto the panel surface of the display panel is a circle.

It is noted that the second signal lines 4 are in direct contact with the first electrode layer 9 so as to achieve conduction without any via hole. With this design, the backplate process costs can be reduced and the production capacity of the product can be increased.

In some embodiments, as shown in FIG. 23, the first signal sub-line 31 further includes a first transfer portion 311, a first transfer hole 2003 is provided in the second planarization layer 200, and the first transfer portion 311 is connected with the second signal sub-lines 32 via the first transfer hole 2003.

It can be known from the above embodiments that the first signal sub-lines 31 are additionally provided with the first transfer portions 311 which may increase the area of the orthographic projections of the first signal sub-lines 31 onto the plane of the display region as well as a volume ratio of the first signal sub-lines 31 in the film layer. In this way, the breakage risk of the first signal sub-lines 31 in an etching process can be reduced in a manufacturing process flow, and the poor circuit contact is prevented from affecting the display effect. Further, the consumption of the etching solution can be reduced and thus the costs are lowered. The addition of the first transfer portion 311 may also reduce the resistance and increase the stability of the signals.

In some embodiments, as shown in FIG. 24, the second signal sub-line 32 further includes a second transfer portion 321, a second transfer hole 3005 is provided in the third planarization layer 300, and the second transfer portion 321 is connected with the second signal line 4 through the second transfer hole 3005. The beneficial effects of this embodiment are similar to the above embodiment and will not be repeated herein.

Illustratively, as shown in FIGS. 17 and 18, at least part of the orthographic projections of the first signal sub-lines 31 onto the plane of the display region are overlapped with the orthographic projections of the second signal sub-lines 32 onto the plane of the display region. The first transfer portion 311 and the second transfer portion 321 are disposed in an overlapping region of the orthographic projection of the first signal sub-line 31 onto the plane of the display region and the orthographic projection of the second signal sub-line 32 onto the plane of the display region. Thus, the orthographic projections of the first transfer hole 2003 and the second transfer portion 3005 onto the plane of the display region are at least partially overlapped, so as to minimize the volumes of the first transfer portion 311 and the second transfer portion 321. The first signal sub-lines 31 may be connected with the second signal sub-lines 32 directly through the via holes disposed in the second planarization layer 200 and the third planarization layer 300, so as to prevent excess traces from occupying the film layer space, and meanwhile avoid increase of the material costs.

Illustratively, as shown in FIG. 7, one end of the first signal line is connected with the first drive circuit and the other end extends to the first node 100 at the periphery of the first light-emitting unit and electrically connects with the first light-emitting unit; one end of the second signal line is connected with the first node 110 and the other end is connected with the second light-emitting unit through a third node 130; the second signal line is further provided with a second node 120 by which the second signal line is electrically connected with the first light-emitting unit.

Illustratively, as shown in FIG. 7, on the second signal line, the second node 120 is located between the first node 110 and the third node 130.

Illustratively, as shown in FIG. 10, on the second signal line, the first node 110 is located between the second node 120 and the third node 130.

It should be noted that when the first signal lines 3 are divided into the first signal sub-lines 31 and the second signal sub-lines 32, the current of the drive circuit will be shunted. Thus, in this connection manner, if the drive circuit for driving the light-emitting units to emit light is the same as in the above embodiment, it is required to properly increase the drive current of the drive circuit of the light-emitting units.

In some embodiments, the first drive circuit 2 of the display panel further includes first drive circuit output points 201. Multiple first signal lines 3 are electrically connected with the first drive circuit 2 via the first drive circuit output points 201. The orthographic projection of at least one of the first drive circuit output points 201 onto the base plate is not overlapped with the orthographic projection of the first electrode (not shown) in the first electrode layer onto the base plate. Thus, the crosstalk between the traces can be reduced and hence the display effect is improved.

In some embodiments, the first drive circuit 2 includes multiple sub-drive circuits, each of which is electrically connected with a sub-light-emitting unit capable of emitting light of a different color.

In some embodiments, each of at least one sub-drive circuit includes one first drive circuit output point 201, and a same first drive circuit output point 201 is electrically connected via the first signal lines with the sub-light-emitting units capable of emitting light of a same color in multiple light-emitting unit groups 1.

In some embodiments, the material of the first signal line 3 is a transparent material.

In some embodiments, the material of the second signal line 4 is a transparent material.

In some embodiments, the first signal line 3 includes a first part located in the transition display region 102 and a second part located in the first display region 101. The material of the second part of the first signal line 3 is a transparent conductive material to increase the transmittance of the first display region 101, so as to ensure the photosensitive element under the first display region 101 can acquire sufficient light.

It is noted that the first signal lines 3 and the second signal lines 4 in the present disclosure are all made of a transparent conductive material.

Illustratively, the materials of the first signal lines 3 and the second signal lines 4 both are ITO.

In some embodiments, multiple light-emitting units included in the display region of the display panel are alternately distributed in odd rows and even rows; and the first drive circuit 2 is disposed in the same row as one of the multiple light-emitting units.

In some embodiments, multiple light-emitting units included in the display region of the display panel are alternately distributed in odd rows and even rows; the first light-emitting unit 11 and the second light-emitting unit 12 are respectively located in two adjacent rows; where,
the first drive circuit 2 is located in the same row as the first light-emitting unit 11;
or, the first drive circuit 2 is located in the same row as the second light-emitting unit 12;
or, the first drive circuit 2 is located at a demarcation line of the odd row and the even row between the first light-emitting unit 11 and the second light-emitting unit 12.

In some embodiments, as shown in FIG. 7 or 10, the display panel further includes: transition light-emitting unit groups 6 and multiple second drive circuits 5.

The transition light-emitting unit groups 6 are located in the transition display region 102. Multiple second drive circuits 5 are located in the transition display region 102, and the second drive circuits 5 are electrically connected with the transition light-emitting unit groups 6. The transition light-emitting unit group 6 includes a third light-emitting unit 61 and a fourth light-emitting unit 62.

The transition signal lines 502 are disposed between the second drive circuit 5 and the third light-emitting unit and between the third light-emitting unit 61 and the fourth light-emitting unit 62, so as to enable the second drive circuit 5 to be electrically connected with the third light-emitting unit 61 and the fourth light-emitting unit 62.

When the first drive circuit 2 is located in an odd row of light-emitting units, the second drive circuit 5 is located in an even row of light-emitting units adjacent to the odd row of light-emitting units. When the first drive circuit 2 is located in an even row of light-emitting units, the second drive circuit 5 is located in an odd row of light-emitting units adjacent to the even row of light-emitting units.

It can be known from the above embodiments that the second drive circuits 5 can also drive the transmission light-emitting units in the transmission display region 102 in the manner of one driving many, to achieve monochromatic light control at the same time. The first drive circuits 2 and the second drive circuits 5 are alternately distributed in the odd rows of light-emitting units and the even rows of light-emitting units. The first drive circuits 2 are used to drive and control the light-emitting units in the first display region 101 and the second drive circuits 5 are used to drive and control the light-emitting units in the transition display region 102. Thus, the transmittance of the first display region 101 can be improved and hence the light sensing effect of the photosensitive element can be enhanced.

In some embodiments, there is an overlapping region between an orthographic projection of at least one of the drive circuit output points onto the plane of the transition display region and an orthographic projection of at least one of the sub-light-emitting units in multiple transition light-emitting units onto the plane of the transition display region.

In this embodiment, since the drive circuits and the light-emitting units are located in different film layers, there is an overlapping region between the orthographic projections of the drive electric output points and the sub-light-emitting units onto the plane of the display region. In this way, the space in the film layer can be fully used while no impact will be brought to the devices.

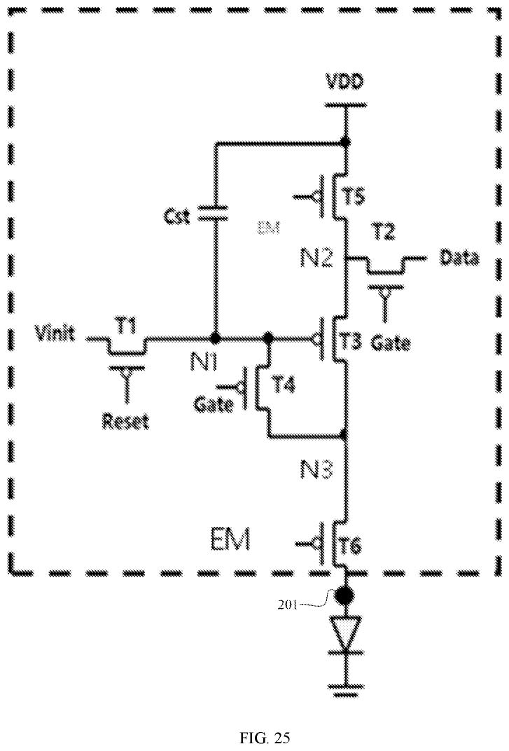

It is noted that the first drive circuits 2 and the second drive circuits 5 in the present disclosure may be the structure of 2T1C, 3T1C, 4T1C, 5T1C, 5T2C, 6T1C or 7T1C. FIG. 25 is an equivalent circuit diagram of a 6T1C pixel drive circuit. As shown in FIG. 25, the drive circuit includes 6 transistors (T1 to T6) and 1 storage capacitor C. Based on the same inventive idea, an embodiment of the present disclosure provides a display apparatus. The display apparatus includes the display panel shown in the above embodiments. Thus, the display apparatus has all features and advantages of the above display panel and will not be described redundantly.

It should be noted that this display apparatus may be any apparatus capable of displaying motion (e.g. video) or stationary images or text. More exactly, it is anticipated that the embodiments may be implemented in multiple types of electronic apparatuses or associated with multiple types of electronic apparatuses. The multiple types of electronic apparatuses may include but not limited to, for example, mobile phone, wireless apparatus, personal digital assistant (PDA), handheld or portable computer, GPS receiver/navigator, camera, MP4 video player, video camera, game console, wrist watch, clock, calculator, television monitor, flat panel display, computer monitor, vehicle display (e.g. odometer display or the like), navigator, cockpit controller and/or display, camera view display (e.g. display of rear camera in a vehicle), electronic photo, electronic billboard or indication board, projector, architectural structure, packaging, aesthetic structure (e.g. image display for a jewel) and the like.

The above embodiments in the present disclosure can be supplemented each other in case of no conflicts.

It should be noted that in the drawings, for illustration clarity, the sizes of the layers and regions may be exaggerated. Furthermore, it may be understood that when an element or layer is referred to as being “on” another element or layer, such element or layer may be directly on the another element or layer or there is an intermediate layer therebetween. Further, it is understood that when an element or layer is referred to as being “under” another element or layer, such element or layer may be directly under the another element or layer, or one or more intermediate elements or layers are present therebetween. In addition, it may also be understood that when a layer or element is referred to as being “between” two layers or elements, such layer or element may be a sole layer between the two layers or elements, or one or more intermediate layers or elements are present. Like reference signs in the descriptions indicate like elements.

In the description of the present disclosure, it is to be understood that orientations or positional relationships indicated by terms such as “center”, “upper”, “lower”, “front”, “rear”, “left”, “right”, “vertical”, “horizontal”, “top”, “bottom”, “inside”, “outside”, or the like are based on orientations or positional relationships shown in the drawings and are used only for convenience and simplification of descriptions of the present disclosure, rather than indicating or implying that the indicated apparatus or element shall have a specific orientation and be configured or operated in a specific orientation. Thus, the terms shall not be understood as limiting of the present disclosure.

The terms “first” and “second” are used only for descriptions and shall not be understood as indicating or implying relative importance or implying a number of the indicated technical features. Thus, features limited by “first” and “second” may explicitly or implicitly include one or more features. In the descriptions of the present disclosure, “plurality” refers to two or more unless otherwise stated clearly.

Other implementations of the present disclosure will be apparent to those skilled in the art from consideration of the specification and practice of the present disclosure herein. The present disclosure is intended to cover any variations, uses, modification or adaptations of the present disclosure that follow the general principles thereof and include common knowledge or conventional technical means in the related art that are not disclosed in the present disclosure. The specification and examples are considered as exemplary only, with a true scope and spirit of the present disclosure being indicated by the following claims.

It is to be understood that the present disclosure is not limited to the precise structure described above and shown in the accompanying drawings, and that various modifications and changes may be made without departing from the scope thereof. The scope of the present disclosure is limited only by the appended claims.

1. A display panel, wherein a display region of the display panel comprises a first display region and a transition display region, and a transmittance of the first display region is greater than a transmittance of the transition display region, wherein the display panel comprises:
light-emitting unit groups in the first display region, wherein at least one light-emitting unit group of the light-emitting unit groups comprises light-emitting units;
first drive circuits in the transition display region;
first signal lines electrically connecting the first drive circuits with the light-emitting unit groups; and
second signal lines electrically connected with the first signal lines and electrically connecting the light-emitting units in the at least one light-emitting unit group.

2. The display panel of claim 1, wherein at least one light-emitting unit of the light-emitting units comprises sub-light-emitting units, at least two sub-light-emitting units of the sub-light-emitting units have different luminous colors, and the second signal lines electrically connect the at least two sub-light-emitting units.

3. The display panel of claim 1, wherein the first signal lines are sequentially distributed on a plane of the display region, and orthographic projections of the first signal lines electrically connected with a same light-emitting unit group onto the plane of the display region do not overlap.

4. The display panel of claim 1, wherein there is an overlapping region between orthographic projections of the first signal lines onto a plane of the display region and orthographic projections of the second signal lines onto the plane of the display region.

5. The display panel of claim 2, wherein the sub-light-emitting units having a same luminous color in a same light-emitting unit group are electrically connected with each other via one of the second signal lines.

6. The display panel of claim 1, wherein orthographic projections of the second signal lines onto a plane of the display region do not overlap.

7. The display panel of claim 2, wherein the first drive circuits are sequentially arranged as a first, second, third . . . and m^{th} drive circuits along a direction away from the first display region, the light-emitting unit groups are sequentially arranged as a first, second, third . . . and n^{th} light-emitting unit groups along a direction away from the transition display region, and the drive circuit and the light-emitting unit group having a same sequence number are electrically connected with each other, wherein m and n are positive integers greater than or equal to 1.

8. The display panel of claim 7, wherein light-emitting units in the n^{th} light-emitting unit group electrically connected with the m^{th} drive circuit are alternately distributed in rows, and the m^{th} drive circuit is in a same row as at least one of the light-emitting units in the n^{th} light-emitting unit group.

9. The display panel of claim 8, wherein at least one first drive circuit of the first drive circuits comprises sub-drive circuits, and the sub-drive circuits are sequentially arranged as a first, second, third . . . and i^{th} sub-drive circuits along the direction away from the first display region; wherein the sub-light-emitting units in a light-emitting unit in a same row as the sub-drive circuits are sequentially arranged as a first, second, third . . . and j^{th} sub-light-emitting units along the direction away from the transition display region; and wherein the sub-drive circuit and the sub-light-emitting unit having a same sequence number are electrically connected with each other, wherein i and j are positive integers greater than or equal to 1.

10. The display panel of claim 9, wherein at least one sub-drive circuit of the sub-drive circuits comprises a drive circuit output point, and the sub-light-emitting units having different luminous colors in the at least one light-emitting unit group are electrically connected with different drive circuit output points respectively.

11. The display panel of claim 9, wherein at least one sub-drive circuit of the sub-drive circuits comprises a drive circuit output point, and the sub-light-emitting units having a same luminous color in the light-emitting unit group are electrically connected with a same drive circuit output point.

12. The display panel of claim 1, wherein the first signal lines comprise first signal sub-lines and second signal sub-lines, and the first signal sub-lines and the second signal sub-lines are in different layers of the display panel.

13. The display panel of claim 12, wherein along a direction perpendicular to a plane of the display region, the display panel comprises a base plate, a metal layer, a first planarization layer, the first signal sub-lines, a second planarization layer, the second signal sub-lines, a third planarization layer, the second signal lines and a first electrode layer which are sequentially stacked, wherein there is an overlapping region between an orthographic projection of the first signal sub-lines onto the plane of the display region and an orthographic projection of the second signal sub-lines onto the plane of the display region.

14. The display panel of claim 13, wherein the first planarization layer has a first via hole and a second via hole, the second planarization layer has a third via hole and a fourth via hole, and the third planarization layer has a fifth via hole and a sixth via hole;
wherein one end of the first signal sub-line is connected with the metal layer through the first via hole, and the other end of the first signal sub-line is connected with the second signal line through the third via hole and the fifth via hole;
wherein one end of the second signal sub-line is connected with the metal layer through the second via hole and the fourth via hole, and the other end of the second signal sub-line is connected with the second signal line through the sixth via hole.

15. The display panel of claim 14, wherein an orthographic projection of the second via hole onto a plate surface of the base plate overlaps an orthographic projection of the fourth via hole onto the plate surface of the base plate; and
an orthographic projection of the third via hole onto the plate surface of the base plate overlaps an orthographic projection of the fifth via hole onto the plate surface of the base plate.

16. The display panel of claim 15,
wherein a side of the second planarization layer close to the base plate comprises a stepped surface, a surface of the stepped surface close to the base plate is in contact with a surface of the metal layer away from the base plate, a seventh via hole is in a region of the second planarization layer close to the metal layer, and an eighth via hole is in the third planarization layer; and one end of the second signal sub-line is connected with the metal layer through the seventh via hole, and the other end of the second signal sub-line is connected with the second signal line through the eighth via hole;
or, wherein a side of the third planarization layer close to the base plate comprises a stepped surface, a surface of the stepped surface close to the base plate is in contact with the first signal sub-line, a ninth via hole is in a region of the third planarization layer close to the first signal sub-line, and a tenth via hole is in the first planarization layer; and one end of the first signal sub-line is connected with the metal layer through the tenth via hole, and the other end of the first signal sub-line is connected with the second signal line through the ninth via hole.

17. The display panel of claim 13, wherein the first signal sub-line further comprises a first transfer portion, a first transfer hole is provided in the second planarization layer, and the first transfer portion is connected with the second signal sub-line through the first transfer hole;
or, the second signal sub-line further comprises a second transfer portion, a second transfer hole is provided in the third planarization layer, and the second transfer portion is connected with the second signal line through the second transfer hole.

18. The display panel of claim 1, wherein a material of a first signal line is a transparent material;
or, a material of a second signal line is a transparent material.

19. The display panel of claim 9, further comprising:
a transition light-emitting unit group in the transition display region and comprising transition light-emitting units;
second drive circuits in the transition display region, wherein the second drive circuits are electrically connected with the transition light-emitting unit group; and
transition signal lines electrically connecting the second drive circuits with the transition light-emitting unit group.

20. (canceled)

21. A display apparatus, comprising a display panel, wherein a display region of the display panel comprises a first display region and a transition display region, and a transmittance of the first display region is greater than a transmittance of the transition display region, wherein the display panel comprises:
light-emitting unit groups in the first display region, wherein at least one light-emitting unit group of the light-emitting unit groups comprises light-emitting units;
first drive circuits in the transition display region;
first signal lines electrically connecting the first drive circuits with the light-emitting unit groups; and
second signal lines electrically connected with the first signal lines and electrically connecting the light-emitting units in the at least one light-emitting unit group.
